(19) United States
(12) Patent Application Publication
(10) Pub. No.: US 2025/0194228 A1
(43) Pub. Date: Jun. 12, 2025

(54) SEMICONDUCTOR DEVICE AND METHOD FOR MANUFACTURING SEMICONDUCTOR DEVICE

(71) Applicant: FUJI ELECTRIC CO., LTD., Kanagawa (JP)

(72) Inventors: Norihiro KOMIYAMA, Matsumoto-city (JP); Seiji NOGUCHI, Matsumoto-city (JP); Yosuke SAKURAI, Azumino-city (JP); Ryutaro HAMASAKI, Matsumoto-city (JP)

(21) Appl. No.: 19/061,930

(22) Filed: Feb. 24, 2025

Related U.S. Application Data
(63) Continuation of application No. PCT/JP2024/001519, filed on Jan. 19, 2024.

(30) Foreign Application Priority Data
Mar. 7, 2023 (JP) 2023-034677

(51) Int. Cl. H10D 84/00; H01L 21/265; H10D 12/00; H10D 62/10; H10D 84/01

(52) U.S. Cl. CPC H10D 84/161; H01L 21/26586; H10D 62/107; H10D 84/0109; H10D 12/481

(57) ABSTRACT

Provided is a semiconductor device including a transistor portion, where the semiconductor device includes: a plurality of trench portions; a drift region of a first conductivity type provided in a semiconductor substrate; a base region of a second conductivity type provided above the drift region; an emitter region of the first conductivity type provided above the base region; a first accumulation region of the first conductivity type provided below the base region; a trench bottom region of the second conductivity type provided below the first accumulation region; and a second accumulation region of the first conductivity type provided at a position deeper than that of the trench bottom region in a depth direction of the semiconductor substrate and having a higher doping concentration than the drift region, where the transistor portion includes a collector region of the second conductivity type on a back surface of the semiconductor substrate.

The contents of the following patent application(s) are incorporated herein by reference:
NO. 2023-034677 filed in JP on Mar. 7, 2023
NO. PCT/JP2024/001519 filed in WO on Jan. 19, 2024.

### BACKGROUND

### 1. Technical Field

The present invention relates to a semiconductor device and a method for manufacturing the semiconductor device.

### 2. Related Art

Patent Document 1 describes ‘. . . may further comprise an electrically floating barrier region 105 of the second conductivity type (in the following also simply referred to as “barrier region”)’.

### PRIOR ART DOCUMENTS

### Patent Documents

Patent Document 1: Japanese Patent Application Publication No. 2019-91892
Patent Document 2: Japanese Patent No. 6472714
Patent Document 3: Japanese Patent No. 5707681

### BRIEF DESCRIPTION OF THE DRAWINGS

FIG. 1 illustrates one example of a top view of a semiconductor device 100.

FIG. 2 illustrates one example of a cross section of the semiconductor device 100.

FIG. 3 illustrates one example of a doping concentration profile including a flat region.

FIG. 4A illustrates a modified example of a cross section of the semiconductor device 100.

FIG. 4B illustrates a modified example of a cross section of the semiconductor device 100.

FIG. 5 illustrates a modified example of a cross section of the semiconductor device 100.

FIG. 6A is a flowchart showing one example of a process to manufacture the semiconductor device 100.

FIG. 6B illustrates one example of a process to manufacture the semiconductor device 100.

FIG. 7A is a flowchart showing a modified example of a process to manufacture the semiconductor device 100.

FIG. 7B illustrates a modified example of a process to manufacture the semiconductor device 100.

### DESCRIPTION OF EXEMPLARY EMBODIMENTS

Hereinafter, the present invention will be described through embodiments of the invention, but the following embodiments do not limit the invention according to claims. In addition, not all combinations of features described in the embodiments are essential to a solution of the invention.

In the present specification, one side in a direction parallel to a depth direction of a semiconductor substrate is referred to as “upper” and another side is referred to as “lower”. One surface of two principal surfaces of a substrate, a layer, or another member is referred to as an upper surface, and another surface is referred to as a lower surface. “Upper”, “lower”, “front”, and “back” directions are not limited to a direction of gravity, or a direction of an attachment to the substrate or the like when a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. It should be noted that a +Z axis direction and a −Z axis direction are directions opposite to each other. If a Z axis direction is described without describing the signs, it means that the direction is parallel to a +Z axis and a −Z axis.

In the present specification, a surface parallel to the upper surface of the semiconductor substrate is referred to as an XY plane, and an orthogonal axis parallel to the upper surface and the lower surface of the semiconductor substrate is referred to as the X axis and the Y axis. In addition, an axis perpendicular to the upper surface and the lower surface of the semiconductor substrate is referred to as the Z axis. The depth direction of a semiconductor substrate may be referred to as the Z axis. It should be noted that, in the present specification, a case where the semiconductor substrate is viewed in the Z axis direction is referred to as a top view. In addition, in the present specification, a direction parallel to the upper surface and the lower surface of the semiconductor substrate may be referred to as a horizontal direction, including an X axis direction and a Y axis direction.

Each example embodiment shows an example in which a first conductivity type is an N type and a second conductivity type is a P type, but the first conductivity type may be the P type and the second conductivity type may be the N type. In this case, conductivity types of the substrate, the layer, a region, and the like in each example embodiment respectively have opposite polarities.

A case where a term such as “same” or “equal” is used in the present specification may include a case where an error due to a variation in manufacturing or the like is included. The error is, for example, within 10%.

In the present specification, a conductivity type of a doping region doped with impurities is described as the P type or the N type. In the present specification, the impurities may particularly mean either donors of the N type or acceptors of the P type, and may be described as dopants. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state.

In the present specification, a description of a P+ type or an N+ type means a higher doping concentration than that of the P type or the N type, and a description of a P− type or an N− type means a lower doping concentration than that of the P type or the N type.

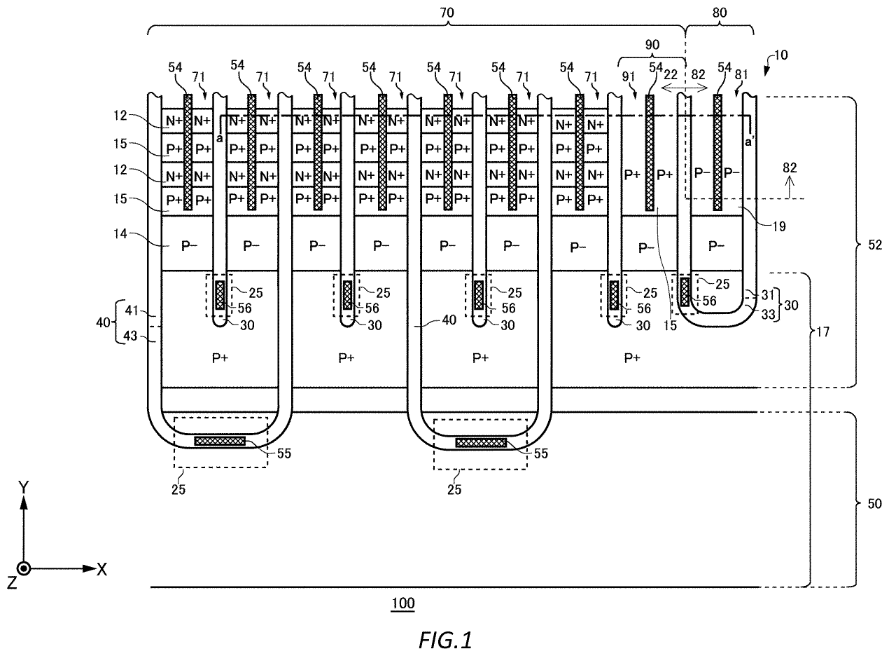

FIG. 1 illustrates one example of a top view of a semiconductor device 100 in the present example. The semiconductor device 100 in the present example is a semiconductor chip including a transistor portion 70 and a diode portion 80. For example, the semiconductor device 100 is a reverse conducting IGBT (RC-IGBT). The transistor portion 70 in the present example includes a boundary portion 90 in a part which is in direct contact with the diode portion 80.

The transistor portion 70 is a region obtained by projecting a collector region 22 provided on a back surface side of a semiconductor substrate 10 onto an upper surface of the semiconductor substrate 10. The collector region 22 has a second conductivity type. The collector region 22 is, for example, of a P+ type. The transistor portion 70 includes a transistor such as an IGBT.

The diode portion 80 is a region obtained by projecting a cathode region 82 provided on a back surface of the semiconductor substrate 10 onto the upper surface of the semiconductor substrate 10. The cathode region 82 has a first conductivity type. The cathode region 82 in the present example is, for example, of an N+ type. The diode portion 80 includes a diode such as a free wheel diode (FWD) provided adjacent to the transistor portion 70 on the upper surface of the semiconductor substrate 10.

A boundary between the collector region 22 and the cathode region 82 is a boundary between the transistor portion 70 and the diode portion 80. That is, the collector region 22 is provided below the boundary portion 90 in the present example.

FIG. 1 shows a region around a chip end portion which is on an edge side of the semiconductor device 100, and does not show another region. An edge termination structure portion may be provided in a region of the semiconductor device 100 in the present example on a negative side in a Y axis direction. The edge termination structure portion reduces electric field strength on an upper surface side of the semiconductor substrate 10. The edge termination structure portion has, for example, a guard ring, a field plate, a RESURF, and a structure combining them. It should be noted that, although the present example describes an edge on the negative side in the Y axis direction for convenience, the same applies to other edges of the semiconductor device 100. The edge termination structure portion may be provided to enclose an active region including the transistor portion 70 and the diode portion 80.

The semiconductor substrate 10 may be a silicon substrate, may be a silicon carbide substrate, or may be a nitride semiconductor substrate such as gallium nitride, or the like. The semiconductor substrate 10 in the present example is a silicon substrate.

The semiconductor device 100 in the present example includes, at a front surface 21 of the semiconductor substrate 10, a gate trench portion 40, a dummy trench portion 30, an emitter region 12, a base region 14, a contact region 15, a well region 17, and an anode region 19. The front surface 21 will be described later. In addition, the semiconductor device 100 in the present example includes an emitter electrode 52 and a gate metal layer 50 which are provided above the front surface 21 of the semiconductor substrate 10.

The emitter electrode 52 is provided above the gate trench portion 40, the dummy trench portion 30, the emitter region 12, the base region 14, the contact region 15, the well region 17, and the anode region 19. In addition, the gate metal layer 50 is provided above a connection portion 25 and the well region 17.

The emitter electrode 52 and the gate metal layer 50 are made of a material containing metal. At least part of the emitter electrode 52 may be made of metal such as aluminum (Al) or of a metal alloy such as an aluminum-silicon alloy (AlSi) or an aluminum-silicon-copper alloy (AlSiCu). At least part of the gate metal layer 50 may be made of metal such as aluminum (Al) or of a metal alloy such as an aluminum-silicon alloy (AlSi) or an aluminum-silicon-copper alloy (AlSiCu). The emitter electrode 52 and the gate metal layer 50 may include a barrier metal layer made of titanium, a titanium compound, or the like under a region made of aluminum or the like. The emitter electrode 52 and the gate metal layer 50 are provided separately from each other.

The emitter electrode 52 and the gate metal layer 50 are provided with an interlayer dielectric film 38 sandwiched therebetween, above the semiconductor substrate 10. FIG. 1 does not show the interlayer dielectric film 38. The interlayer dielectric film 38 includes a contact hole 54, a contact hole 55, and a contact hole 56 which are provided penetrating therethrough.

The contact hole 55 electrically connects the gate metal layer 50 and a gate conductive portion in the transistor portion 70 to each other via the connection portion 25. A plug layer made of tungsten or the like may be formed within the contact hole 55.

The contact hole 56 connects the emitter electrode 52 and a dummy conductive portion in the dummy trench portion 30 to each other. A plug layer made of tungsten or the like may be formed within the contact hole 56.

The connection portion 25 is connected to a front surface side metal layer such as the emitter electrode 52 or the gate metal layer 50. In one example, the connection portion 25 is provided between the gate metal layer 50 and the gate conductive portion. The connection portion 25 in the present example may be provided extending in an X axis direction, and be electrically connected to the gate conductive portion. The connection portion 25 may also be provided between the emitter electrode 52 and the dummy conductive portion. The connection portion 25 is made of a conductive material such as polysilicon doped with an impurity. The connection portion 25 in the present example is polysilicon doped with an impurity of an N type (N+). The connection portion 25 is provided above the front surface 21 of the semiconductor substrate 10 via a dielectric film such as an oxide film, or the like.

Gate trench portions 40 are examples of a plurality of trench portions extending in a

predetermined extending direction on a front surface 21 side of the semiconductor substrate 10. The gate trench portions 40 are arrayed at a predetermined interval along a predetermined array direction (the X axis direction in the present example). The gate trench portion 40 in the present example may include two extending parts 41 which extend along an extending direction (the Y axis direction in the present example) parallel to the front surface 21 of the semiconductor substrate 10 and perpendicular to the array direction, and a connection part 43 which connects the two extending parts 41 to each other.

At least part of the connection part 43 is preferably formed in a curved line. Connecting end portions of the two extending parts 41 of the gate trench portion 40 to each other can reduce electric field strength at the end portions of the extending parts 41. In the connection part 43 of the gate trench portion 40, the gate metal layer 50 may be electrically connected to the gate conductive portion via the connection portion 25.

Dummy trench portions 30 are examples of a plurality of trench portions extending in a predetermined extending direction on the front surface 21 side of the semiconductor substrate 10. The dummy trench portion 30 is a trench portion electrically connected to the emitter electrode 52. Similarly to the gate trench portions 40, the dummy trench portions 30 are arrayed at a predetermined interval along a predetermined array direction (the X axis direction in the present example). The dummy trench portion 30 in the present example has an I shape on the front surface 21 of the semiconductor substrate 10. Similarly to the gate trench portion 40, the dummy trench portion 30 may have a U shape on the front surface 21 of the semiconductor substrate 10. That is, the dummy trench portion 30 may include two extending parts 31 which extend along the extending direction, and a connection part 33 which connects the two extending parts to each other.

The transistor portion 70 in the present example has a structure in which two gate trench portions 40 and two dummy trench portions 30 are repetitively arrayed. That is, the transistor portion 70 in the present example includes the gate trench portions 40 and the dummy trench portions 30 at a ratio of 1:1. For example, the transistor portion 70 includes one dummy trench portion 30 between two extending parts 41.

It is to be noted that the ratio between the gate trench portions 40 and the dummy trench portions 30 is not limited to that in the present example. The ratio of the gate trench portions 40 may be greater than the ratio of the dummy trench portions 30, or the ratio of the dummy trench portions 30 may be greater than the ratio of the gate trench portions 40. The ratio between the gate trench portions 40 and the dummy trench portions 30 may be 2:3, or may be 2:4. In addition, the transistor portion 70 may not include the dummy trench portions 30 with all trench portions being the gate trench portions 40.

The well region 17 is a region of the second conductivity type provided closer to the front surface 21 of the semiconductor substrate 10 than a drift region 18 described later. The well region 17 is one example of a well region provided on a side of a periphery of the active region. The well region 17 is, for example, of the P+ type. The well region 17 is formed within a predetermined range from an end portion of an active region on a side where the gate metal layer 50 is provided. A diffusion depth of the well region 17 may be greater than depths of the gate trench portion 40 and the dummy trench portion 30. Parts of the gate trench portion 40 and the dummy trench portion 30 on a gate metal layer 50 side are formed in the well region 17. Bottoms of ends of the gate trench portion 40 and the dummy trench portion 30 in the extending direction may be covered with the well region 17.

The contact hole 54 is formed above each of the emitter region 12 and the contact region 15 in the transistor portion 70. The contact hole 54 is not provided above well regions 17 provided at both ends in the Y axis direction. In this manner, one or more contact holes 54 are formed in the interlayer dielectric film. The one or more contact holes 54 may be provided extending in the extending direction.

A mesa portion 71 is a mesa portion provided in direct contact with the trench portion in a plane parallel to the front surface 21 of the semiconductor substrate 10. The mesa portion may be a part, which is sandwiched between two trench portions adjacent to each other, of the semiconductor substrate 10, and may be a part from the front surface 21 of the semiconductor substrate 10 to a depth of a lowermost bottom portion of each trench portion. An extending part of each trench portion may be defined as one trench portion. That is, a region sandwiched between two extending parts may be defined as a mesa portion.

The mesa portion 71 is provided in direct contact with at least one of the dummy trench portion 30 or the gate trench portion 40 in the transistor portion 70. The mesa portion 71 includes, at the front surface 21 of the semiconductor substrate 10, the well region 17, the emitter region 12, the base region 14, and the contact region 15. In the mesa portion 71, the emitter region 12 and the contact region 15 are alternately provided in the extending direction.

The base region 14 is a region of the second conductivity type provided on the front surface 21 side of the semiconductor substrate 10. The base region 14 is, for example, of a P− type. Base regions 14 may be provided in both end portions of the mesa portion 71 and a mesa portion 81 in the Y axis direction, at the front surface 21 of the semiconductor substrate 10. It should be noted that FIG. 1 shows only the base region 14, which is provided in one of the end portions in the Y axis direction, of the base regions 14.

The emitter region 12 is a region of the first conductivity type having a higher doping concentration than the drift region 18. The emitter region 12 in the present example is, for example, of the N+ type. One example of a dopant in the emitter region 12 is arsenic (As). The emitter region 12 is provided in contact with the gate trench portion 40 on the front surface 21 in the mesa portion 71. The emitter region 12 may be provided extending in the X axis direction from one to another of the two trench portions sandwiching the mesa portion 71. The emitter region 12 is also provided below the contact hole 54.

In addition, the emitter region 12 may be in contact with or may not be in contact with the dummy trench portion 30. The emitter region 12 in the present example is in contact with the dummy trench portion 30.

The contact region 15 is a region of the second conductivity type provided above the base region 14 and having a higher doping concentration than the base region 14. The contact region 15 in the present example is, for example, of the P+ type. The contact region 15 in the present example is provided on the front surface 21 in the mesa portion 71. The contact region 15 may be provided extending in the X axis direction from one to another of the two trench portions sandwiching the mesa portion 71.

The contact region 15 may be in contact with or may not be in contact with the gate trench portion 40 or the dummy trench portion 30. The contact region 15 in the present example is in contact with the dummy trench portion 30 and the gate trench portion 40. The contact region 15 is also provided below the contact hole 54.

In a depth direction of the semiconductor substrate 10, a thickness of the contact region 15 may be larger than a thickness of the emitter region 12. A lower end of the contact region 15 may be provided at a position deeper than that of a lower end of the emitter region 12.

The mesa portion 81 is provided in a region sandwiched between dummy trench portions 30 adjacent to each other, in the diode portion 80. The mesa portion 81 includes the anode region 19 on the front surface 21 of the semiconductor substrate 10. The mesa portion 81 in the present example includes the anode region 19 and the well region 17 on the negative side in the Y axis direction.

The anode region 19 is a region of the second conductivity type provided on the front surface 21 side of the semiconductor substrate 10. A doping concentration in the anode region 19 may be lower than a doping concentration in the base region 14. The anode region 19 in the present example is, for example, of the P− type. The anode region 19 in the present example is provided on the front surface 21 in the mesa portion 81. The anode region 19 may be provided extending in the X axis direction from one to another of two dummy trench portions 30 sandwiching the mesa portion 81. The anode region 19 may be in contact with or may not be in contact with the dummy trench portion 30. The anode region 19 in the present example is in contact with the dummy trench portion 30.

The boundary portion 90 is a region provided in the transistor portion 70 and in direct contact with the diode portion 80. The boundary portion 90 may not include the emitter region 12. In one example, trench portions in the boundary portion 90 are dummy trench portions 30. The boundary portion 90 in the present example is arranged such that the dummy trench portions 30 are at its both ends in the X axis direction. In the boundary portion 90, at least one of the dummy trench portions 30 may be set to a potential different from a gate potential.

A mesa portion 91 is provided in the boundary portion 90. The mesa portion 91 includes the contact region 15 on the front surface 21 of the semiconductor substrate 10. The mesa portion 91 in the present example includes the base region 14 and the well region 17 on the negative side in the Y axis direction.

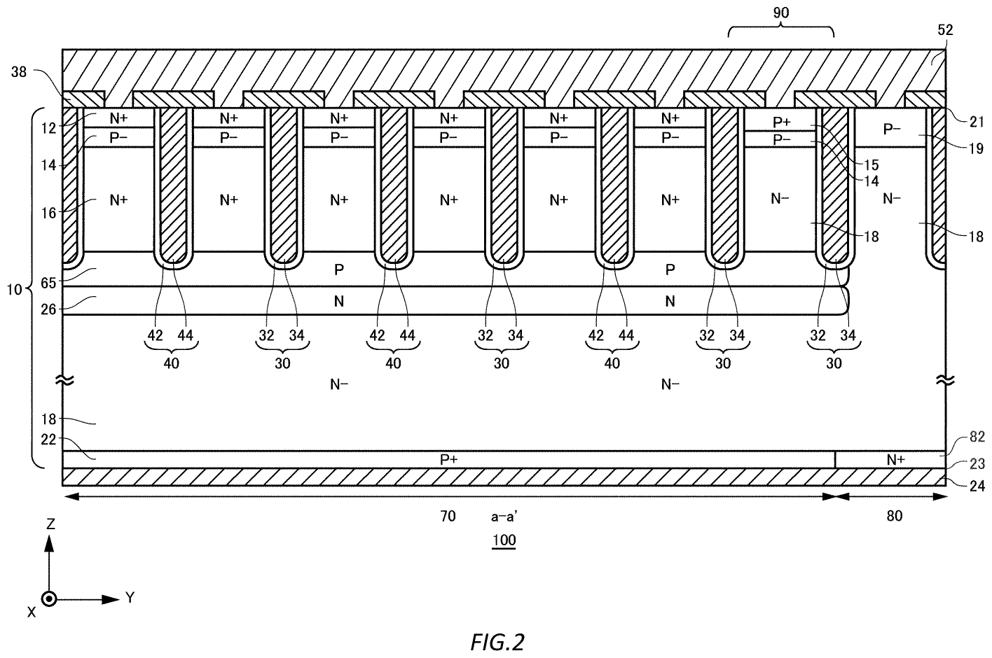

FIG. 2 shows one example of a cross section a-a′ in FIG. 1. The cross section a-a′ is an XZ plane passing through the emitter region 12 in the transistor portion 70. The semiconductor device 100 in the present example has, in the cross section a-a′, the semiconductor substrate 10 including the emitter region 12, the base region 14, the contact region 15, a first accumulation region 16, the drift region 18, the anode region 19, a trench bottom region 65, a second accumulation region 26, the collector region 22, and the cathode region 82; the interlayer dielectric film 38; the emitter electrode 52; and a collector electrode 24. The collector electrode 24 is one example of a back surface side metal layer provided in contact with a back surface 23 of the semiconductor substrate 10. The emitter electrode 52 is formed above the semiconductor substrate 10 and the interlayer dielectric film 38.

The drift region 18 is a region of a first conductivity type provided in the semiconductor substrate 10. The drift region 18 in the present example is, for example, of an N− type. The drift region 18 may be a region, which is left with no other doping region formed, of the semiconductor substrate 10. That is, a doping concentration in the drift region 18 may be a doping concentration in the semiconductor substrate 10.

The first accumulation region 16 is a region of the first conductivity type provided below the base region 14 in the semiconductor substrate 10. A doping concentration in the first accumulation region 16 is higher than the doping concentration in the drift region 18. The first accumulation region 16 in the present example is, for example, of the N+ type. The doping concentration in the first accumulation region 16 may be 4.0E15 cm⁻³ or higher, and may be 1.0E17 cm⁻³ or lower.

The first accumulation region 16 may be provided in the transistor portion 70, and may not be provided in the diode portion 80 and the boundary portion 90. The first accumulation region 16 may also be provided in the boundary portion 90. The first accumulation region 16 may be provided in both the transistor portion 70 and the diode portion 80. Providing the first accumulation region 16 can increase a carrier injection enhancement effect (IE effect) and reduce an on-state voltage of the transistor portion 70.

The first accumulation region 16 may have one or more doping concentration peaks. In a depth direction of the semiconductor substrate 10, the first accumulation region 16 may have one doping concentration peak or may have a plurality of doping concentration peaks. The doping concentration in the first accumulation region 16 may have a profile including a flat region. The profile including the flat region will be described later.

A thickness of the first accumulation region 16 in the depth direction of the semiconductor substrate 10 may be larger than a thickness of the trench bottom region 65 described later, or may be larger than a thickness of the second accumulation region 26. The thickness of the first accumulation region 16 may be equal to or larger than 20% and equal to or smaller than 80% of a trench depth of a plurality of trench portions. A region having a doping concentration equal to or higher than 50% of a maximum doping concentration in the first accumulation region 16 may have a thickness of 1 μm or larger and 4 μm or smaller.

The trench bottom region 65 is a region of a second conductivity type provided below the first accumulation region 16. A doping concentration in the trench bottom region 65 in the present example is higher than the doping concentration in the base region 14. The trench bottom region 65 in the present example is, for example, of a P type. The doping concentration in the trench bottom region 65 may be 1.0E14 cm⁻³ or higher, and may be 1.0E16 cm⁻³ or lower.

The trench bottom region 65 in the present example is provided such that an upper end thereof is in contact with a lower end of the first accumulation region 16. The upper end of the trench bottom region 65 may not be in contact with the lower end of the first accumulation region 16.

The trench bottom region 65 in the present example is provided such that a lower end thereof is in contact with an upper end of the second accumulation region 26. The lower end of the trench bottom region 65 may not be in contact with the upper end of the second accumulation region 26.

The trench bottom region 65 in the present example may be provided extending from a lower end of one trench portion of the plurality of trench portions to a lower end of another trench portion, which faces the one trench portion, of the plurality of trench portions, in a trench array direction of the plurality of trench portions. The trench bottom region 65 may be provided extending from a lower end of one trench portion of the plurality of trench portions beyond a lower end of another trench portion, which faces the one trench portion, of the plurality of trench portions, to a lower end of a trench portion adjacent to the another trench portion, which faces the one trench portion, of the plurality of trench portions. That is, the trench bottom region 65 may be provided extending beyond lower ends of a plurality of trench portions, a number of which is two or more.

The thickness of the trench bottom region 65 in the depth direction of the semiconductor substrate 10 may be larger than the thickness of the second accumulation region 26 described later. The thickness of the trench bottom region 65 in the depth direction of the semiconductor substrate 10 may be equal to or larger than 20% and equal to or smaller than 100% of the trench depth of the plurality of trench portions. The thickness of the trench bottom region 65 in the depth direction of the semiconductor substrate 10 may be 1 μm or larger and 5 μm or smaller.

The second accumulation region 26 is a region of the first conductivity type provided at a position deeper than that of the trench bottom region 65 in the depth direction of the semiconductor substrate 10. A doping concentration in the second accumulation region 26 may be lower than the doping concentration in the first accumulation region 16. The doping concentration in the second accumulation region 26 may be 5.0E14 cm⁻³ or higher, and may be 1.0E17 cm⁻³ or lower.

The doping concentration in the second accumulation region 26 in the present example is higher than the doping concentration in the drift region 18. The second accumulation region 26 in the present example is, for example, of the N type. Although details will be described later, providing the second accumulation region 26 can control the thickness of the trench bottom region 65.

The collector electrode 24 is formed on the back surface 23 of the semiconductor

substrate 10. The collector electrode 24 is made of a conductive material such as metal. The collector electrode 24 may be made of a conductive material which is the same as or different from that of the emitter electrode 52 and the gate metal layer 50.

The gate trench portion 40 includes a gate trench, a gate dielectric film 42, and a gate conductive portion 44 which are formed on the front surface 21. The gate dielectric film 42 is formed covering an inner wall of the gate trench. The gate dielectric film 42 may be formed by oxidizing or nitriding a semiconductor on the inner wall of the gate trench. The gate conductive portion 44 is formed farther inward than the gate dielectric film 42 within the gate trench. The gate dielectric film 42 insulates the gate conductive portion 44 and the semiconductor substrate 10 from each other. The gate conductive portion 44 is made of a conductive material such as polysilicon. The gate trench portion 40 is covered with the interlayer dielectric film 38 on the front surface 21.

In the depth direction of the semiconductor substrate 10, the gate conductive portion 44 includes a region facing the base region 14 which is adjacent to the gate conductive portion 44 with the gate dielectric film 42 sandwiched therebetween on a mesa portion 71 side. In response to application of a predetermined voltage to the gate conductive portion 44, a channel is formed by an electron inversion layer in a surface layer, which is in contact with the gate trench and is a boundary surface between the base region 14 and the gate trench, of the base region 14.

The dummy trench portion 30 may have a same structure as that of the gate trench portion 40. The dummy trench portion 30 includes a dummy trench, a dummy dielectric film 32, and a dummy conductive portion 34 which are formed on the front surface 21 side. The dummy dielectric film 32 is formed covering an inner wall of the dummy trench. The dummy conductive portion 34 is formed within the dummy trench, and is formed farther inward than the dummy dielectric film 32. The dummy dielectric film 32 insulates the dummy conductive portion 34 and the semiconductor substrate 10 from each other. The dummy trench portion 30 is covered with the interlayer dielectric film 38 on the front surface 21.

The interlayer dielectric film 38 is provided on the front surface 21. The emitter electrode 52 is provided above the interlayer dielectric film 38. The interlayer dielectric film 38 may be provided with one or more trench contact portions to electrically connect the emitter electrode 52 and the semiconductor substrate 10 to each other. Similarly, the contact hole 55 and the contact hole 56 may include a trench contact portion provided penetrating through the interlayer dielectric film 38.

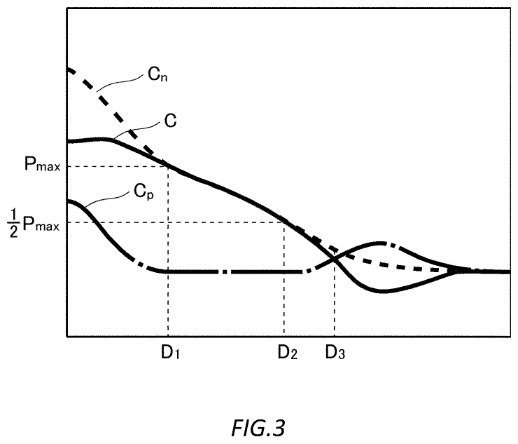

FIG. 3 illustrates one example of a doping concentration profile including a flat region. In the present specification, a doping concentration in the first accumulation region 16 having the doping concentration profile including the flat region means that a region having a doping concentration equal to or higher than 50% of a maximum doping concentration in the first accumulation region 16 occupies a thickness equal to or larger than 60% and equal to or smaller than 100% of a thickness of the first accumulation region 16 in a depth direction of the semiconductor substrate 10.

In FIG. 3, a dotted line indicates a doping concentration of a dopant of a first conductivity type, and is indicated by a symbol Cn. A dash-dotted line indicates a doping concentration of a dopant of a second conductivity type, and is indicated by a symbol Cp. A solid line indicates an actual doping concentration obtained from a sum of Cn and Cp, and is indicated by a symbol C.

In FIG. 3, a position indicated by D₁ is a position of an upper end of the first accumulation region 16. In FIG. 3, a position indicated by D₃ is a position of a lower end of the first accumulation region 16. In one example, the doping concentration in the first accumulation region 16 is at a maximum value Pmax at the position D₁.

In FIG. 3, a position indicated by D2 is a position where the doping concentration is 50% of the maximum doping concentration in the first accumulation region 16. In one example, if the doping concentration profile includes the flat region, a relational expression shown in Expression 1 described below holds. The doping concentration in the first accumulation region 16 having the doping concentration profile including the flat region can suppress a decrease in clamp withstand capability.

$$0.6 \leq \frac{{D}_{2} - {D}_{1}}{{D}_{3} - {D}_{1}} \leq 1 \qquad ( Expression 1 )$$

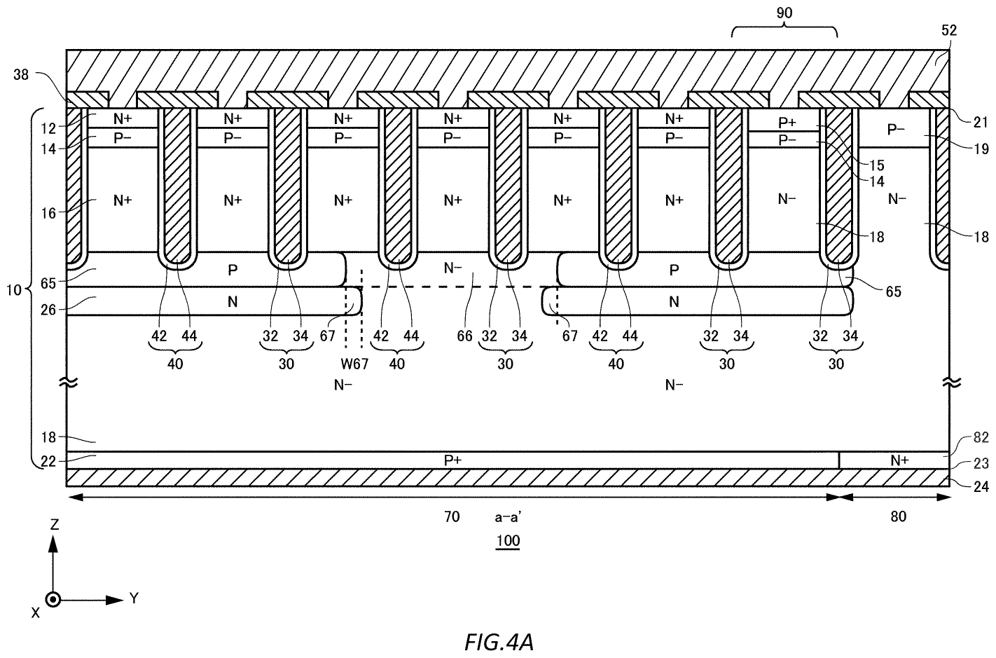

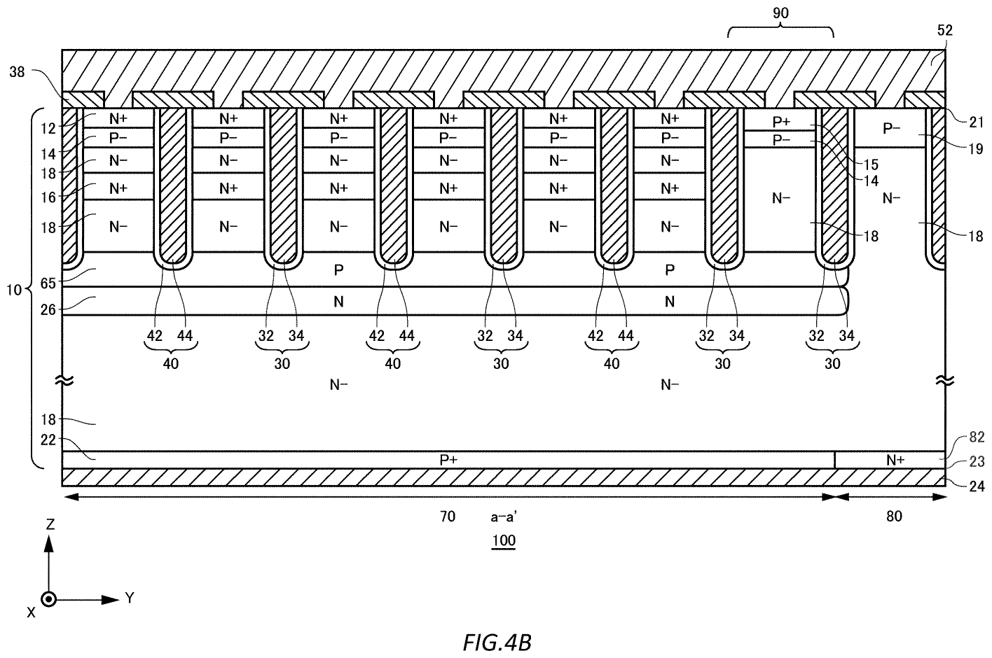

FIG. 4A shows a modified example of the cross section a-a′ in FIG. 1. The modified example shown in FIG. 4A is different from an example embodiment shown in FIG. 2 in that a carrier passage region 66 and a protruding part 67 are provided.

The carrier passage region 66 is a region of a first conductivity type which is not provided with the trench bottom region 65 below the first accumulation region 16. The carrier passage region 66 may be a region in which the drift region 18 has been left with no additional ion implanted. That is, a doping concentration in the carrier passage region 66 may be the same as a doping concentration in the drift region 18. Providing the carrier passage region 66 can lower an electronic barrier and reduce an on-state power loss Eon.

The trench bottom region 65 may be provided in a mesa portion in the region provided with the carrier passage region 66. In addition, the first accumulation region 16 may be provided in the mesa portion in the region provided with the carrier passage region 66.

The protruding part 67 is a part, which protrudes from below the trench bottom region

65 beyond an end portion of the trench bottom region 65 toward an outside of the trench bottom region 65 in a trench array direction of a plurality of trench portions, of the second accumulation region 26. Providing the protruding part 67 can reliably control a thickness of the trench bottom region 65.

In the trench array direction of the plurality of trench portions, a distance between an outer end portion of the trench bottom region 65 and an outer end portion of the second accumulation region 26 is referred to as a width W67 of the protruding part. The width W67 may be larger than 0 and equal to or smaller than a width between trenches adjacent to each other. The width W67 may be equal to or larger than a width between trenches adjacent to each other.

FIG. 4B shows a modified example of the cross section a-a′ in FIG. 1. The modified example shown in FIG. 4B is different from the example embodiment shown in FIG. 2 in that the drift region 18 is provided between the base region 14 and the trench bottom region 65.

In the modified example shown in FIG. 4B, a doping concentration in the first accumulation region 16 has one doping concentration peak. The doping concentration in the first accumulation region 16 may have a plurality of doping concentration peaks. The doping concentration in the first accumulation region 16 may have a profile including a flat region.

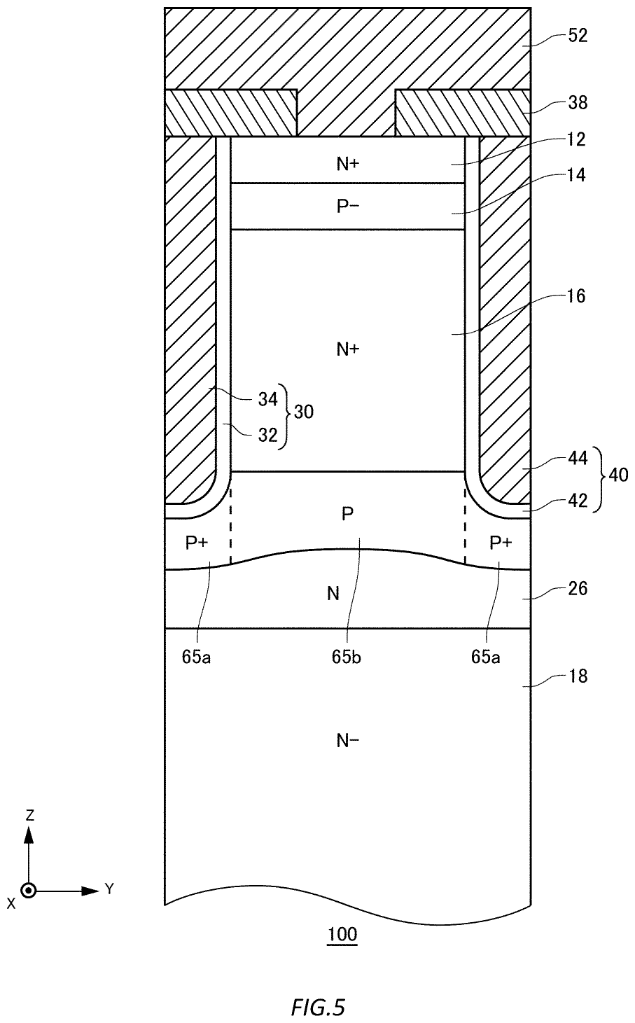

FIG. 5 illustrates one example of a vicinity of one mesa portion 71 in the transistor portion 70 in the present example. In the example shown in FIG. 5, the trench bottom region 65 includes first regions 65a provided below a plurality of trench portions, and second regions 65b provided below mesa portions 71 sandwiched between the plurality of trench portions.

The trench bottom region 65 may have a doping concentration distribution in a trench array direction of the plurality of trench portions. A doping concentration in the first regions 65a may be higher than a doping concentration in the second regions 65b. In the present specification, the doping concentration in the first regions 65a may be an average doping concentration in the trench bottom region 65 below the plurality of trench portions. The first regions 65a and the second regions 65b may have a same doping concentration.

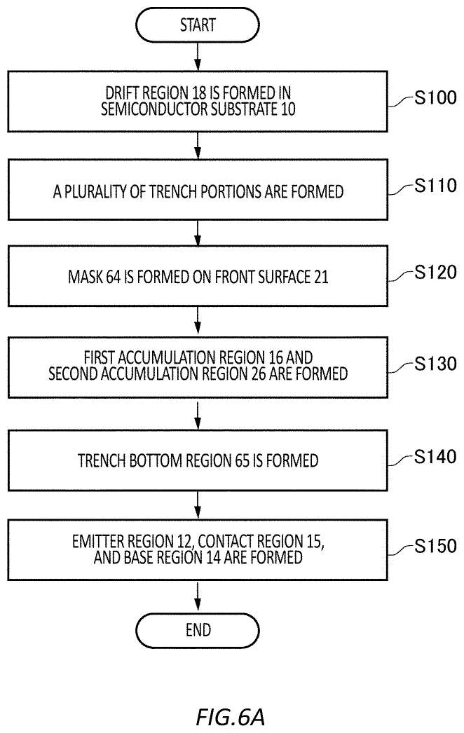

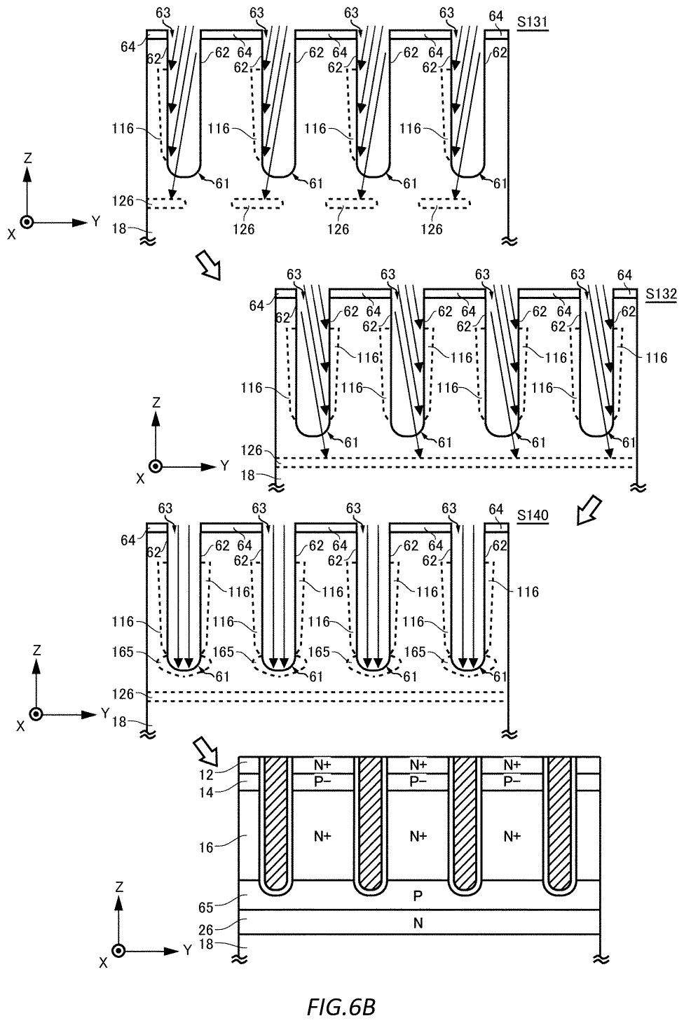

FIG. 6A is a flowchart showing one example of a process to manufacture the semiconductor device 100. The present example shows one example of the flowchart of the process to manufacture the semiconductor device 100, but the process to manufacture the semiconductor device 100 is not limited to this. In a step S100, the drift region 18 is formed in the semiconductor substrate 10. A step of forming the drift region 18 in the semiconductor substrate 10 will not be described in detail in the present specification since the drift region can be formed with a conventional method used by persons skilled in the art.

In a step S110, a plurality of trench portions are formed on the front surface 21 of the semiconductor substrate 10. This forms a bottom portion 61, a side wall 62, and an opening 63 of a trench portion. The bottom portion 61, the side wall 62, and the opening 63 will be described later.

In a step S120, a mask 64 is formed on the front surface 21 of the semiconductor substrate 10. The mask 64 may be any mask such as photoresist.

In a step S130, the first accumulation region 16 and the second accumulation region 26 are formed by ion-implanting dopants from the front surface 21 side of the semiconductor substrate 10. The implanted dopants may be phosphorus.

In the step S130, the dopants may be ion-implanted from a direction having a predetermined slope with respect to a depth direction of the semiconductor substrate 10. A step of forming the first accumulation region 16 may include a step of implanting dopants into side walls 62 of the plurality of trench portions via openings 63 of the plurality of trench portions from a direction having a predetermined slope with respect to the depth direction of the semiconductor substrate 10. A step of forming the second accumulation region 26 may include a step of implanting dopants into bottom portions 61 of the plurality of trench portions via the openings 63 of the plurality of trench portions from a direction having a predetermined slope with respect to the depth direction of the semiconductor substrate 10. The predetermined slope when the dopants are ion-implanted is not particularly limited as long as it is at an angle which allows dopant irradiation onto both the bottom portion 61 and the side wall 62 of the trench portion.

In a step S140, the trench bottom region 65 is formed by ion-implanting dopants from the front surface 21 side of the semiconductor substrate 10. The implanted dopants may be boron, or may be aluminum.

In the step S140, a step of forming the trench bottom region 65 may include a step of implanting dopants into the bottom portions 61 of the plurality of trench portions via the openings 63 of the plurality of trench portions in the depth direction of the semiconductor substrate 10. This makes it possible to implant the dopants near the bottom portion 61 of the trench portion and to form the trench bottom region 65.

The step S130 and the step S140 may be performed in reverse order. That is, in the above description as one example, the first accumulation region 16 and the second accumulation region 26 are formed first, and then the trench bottom region 65 is formed, but the trench bottom region 65 may be formed first, and then the first accumulation region 16 and the second accumulation region 26 may be formed.

In a step S150, the emitter region 12, the contact region 15, and the base region 14 are formed in the semiconductor substrate 10. Regions described above will not be described in detail in the present specification since they can be formed with a conventional method used by persons skilled in the art.

FIG. 6B illustrates one example of a process to manufacture the semiconductor device 100. FIG. 6B illustrates a YZ cross section of the semiconductor substrate 10 in each step in FIG. 6A.

The step S130 may include a step S131 and a step S132 in which dopants are ion-implanted diagonally from upper right and diagonally from upper left, respectively, in FIG. 6B. An acceleration voltage for ion implantation in the step S130 may be 0.1 MeV or higher, and may be 2.6 MeV or lower.

In the step S131, the dopants may be ion-implanted from a direction having a predetermined slope with respect to the depth direction of the semiconductor substrate 10. In the step S131, a first ion implantation region 116 is formed on one of side walls 62 of each trench portion of the plurality of trench portions via the opening 63 of each trench portion of the plurality of trench portions. The first ion implantation region 116 is a region which becomes the first accumulation region 16 through annealing processing.

In the step S132, the dopants may be ion-implanted from a direction having a predetermined slope with respect to the depth direction of the semiconductor substrate 10. In the step S132, a first ion implantation regions 116 is formed on another of the side walls 62 of each trench portion of the plurality of trench portions via the opening 63 of each trench portion of the plurality of trench portions.

In both the step S131 and the step S132, dopants may be ion-implanted into the bottom portions 61 of the plurality of trench portions via the openings 63 of the plurality of trench portions from a direction having a predetermined slope with respect to the depth direction of the semiconductor substrate 10. In the step S131 and the step S132, second ion implantation regions 126 are formed below the bottom portions 61 of the plurality of trench portions. A second ion implantation region 126 is a region which becomes the second accumulation region 26 through annealing processing.

In the step S130, a step of forming the first ion implantation regions 116 and a step of forming the second ion implantation regions 126 may be performed simultaneously, or may be performed separately. In an example embodiment shown in FIG. 6B, they are formed simultaneously through an ion implantation step. That is, in FIG. 6B, the first accumulation region 16 is formed by implanting the dopants into the side walls 62 of the plurality of trench portions via the openings 63 of the plurality of trench portions, and the second accumulation region 26 is formed by implanting the dopants into the bottom portions 61 of the plurality of trench portions via the openings 63 of the plurality of trench portions.

In the step S130, a doping concentration distribution including a flat profile can be

formed by implanting the dopants into the side walls 62 of the plurality of trench portions via the openings 63 of the plurality of trench portions. In addition, implanting the dopants into the bottom portions 61 of the plurality of trench portions via the openings 63 of the plurality of trench portions can form the second ion implantation region 126 at a position which is below the bottom portion 61 of the trench portion and is deeper than a position of a region in which a trench bottom implantation region 165 is formed.

In the step S140, the dopants are implanted from the front surface 21 side of the semiconductor substrate 10 via the openings 63 of the plurality of trench portions into the bottom portions 61 of the plurality of trench portions, to form trench bottom implantation regions 165. The trench bottom implantation region 165 is a region which becomes the trench bottom region 65 through annealing processing.

Annealing processing on the first ion implantation region 116, the second ion implantation region 126, and the trench bottom implantation region 165 may be performed at any timing. In one example, the annealing processing is performed after the step S140. The annealing processing may be performed between the step S130 and the step S140.

In the present example, in the step S140, the dopants are implanted above the second ion implantation region 126. This makes it possible to suppress thermal diffusion in the depth direction of the trench bottom implantation region 165 during the annealing processing and to control a thickness of the trench bottom region 65 in the depth direction of the semiconductor substrate 10. That is, a position of a lower end of the trench bottom region 65 is limited by the second accumulation region 26, so that the thickness of the trench bottom region 65 can be controlled to be smaller than in a case where the second accumulation region 26 is not provided.

The semiconductor device 100 in the present example includes the second accumulation region 26, so that the thickness of the trench bottom region 65 is smaller than in a comparative example in which the second accumulation region 26 is not provided. An effect of forming the trench bottom region 65 thin will be described with reference to Table 1 and Table 2.

Table 1 shows presence or absence of a gate oscillation during a turn-on in the comparative example and each example embodiment. Here, Example Embodiments 1 to 3 are different in an implantation angle at which the dopants are implanted in the step S130. The implantation angle is the smallest in Example Embodiment 1, is the greatest in Example Embodiment 3, and is between the smallest and the greatest in Example Embodiment 2.

As shown in Table 1, in the comparative example in which the second accumulation region 26 was not provided and the thickness of the trench bottom region 65 was large, the gate oscillation was observed for any gate resistance value with a relative value of a gate resistance of 10 or greater. On the other hand, in Example Embodiments 1 to 3 in which the thickness of the trench bottom region 65 was smaller than in the comparative example due to formation of the second accumulation region 26, the gate oscillation was not observed for any gate resistance value tested.

TABLE 1

| | | COMPARATIVE | EXAMPLE | EXAMPLE | EXAMPLE |
|---|---|---|---|---|---|
| | | EXAMPLE | EMBODIMENT 1 | EMBODIMENT 2 | EMBODIMENT 3 |
| GATE RESISTANCE | 1 | ABSENT | ABSENT | ABSENT | ABSENT |
| [RELATIVE VALUE] | 10 | PRESENT | ABSENT | ABSENT | ABSENT |
| | 20 | PRESENT | ABSENT | ABSENT | ABSENT |
| | 30 | PRESENT | ABSENT | ABSENT | ABSENT |
| | 60 | PRESENT | ABSENT | ABSENT | ABSENT |

Table 2 shows presence or absence of an arm short-circuit oscillation in the comparative example and each example embodiment. As shown in Table 2, in the comparative example in which the second accumulation region 26 was not provided and the thickness of the trench bottom region 65 was large, the arm short-circuit oscillation was observed for any power source voltage tested. On the other hand, in Example Embodiments 1 to 3 in which the thickness of the trench bottom region 65 was smaller than in the comparative example due to formation of the second accumulation region 26, only a slight arm short-circuit oscillation was observed in Example Embodiment 3 when the power source voltage was 500 V, and the arm short-circuit oscillation was not observed in the other example embodiments.

TABLE 2

| | | COMPARATIVE | EXAMPLE | EXAMPLE | EXAMPLE |
|---|---|---|---|---|---|
| | | EXAMPLE | EMBODIMENT 1 | EMBODIMENT 2 | EMBODIMENT 3 |
| POWER SOURCE | 500 | PRESENT | ABSENT | ABSENT | PRESENT |
| VOLTAGE | 600 | PRESENT | ABSENT | ABSENT | ABSENT |
| [V] | 700 | PRESENT | ABSENT | ABSENT | ABSENT |
| | 800 | PRESENT | ABSENT | ABSENT | ABSENT |

As shown in Table 1 and Table 2, the semiconductor device 100 in the present example can suppress the gate oscillation and the arm short-circuit oscillation, by forming the second accumulation region 26 to control the thickness of the trench bottom region 65 to be smaller than in the comparative example. In addition, forming the trench bottom region 65 can reduce an on-state power loss Eon.

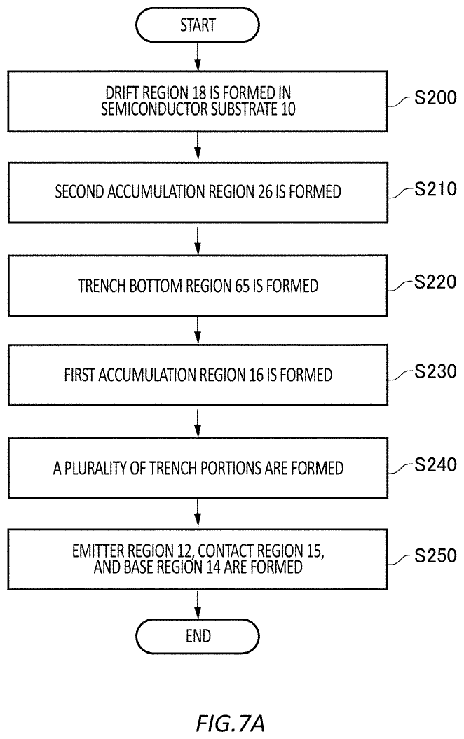

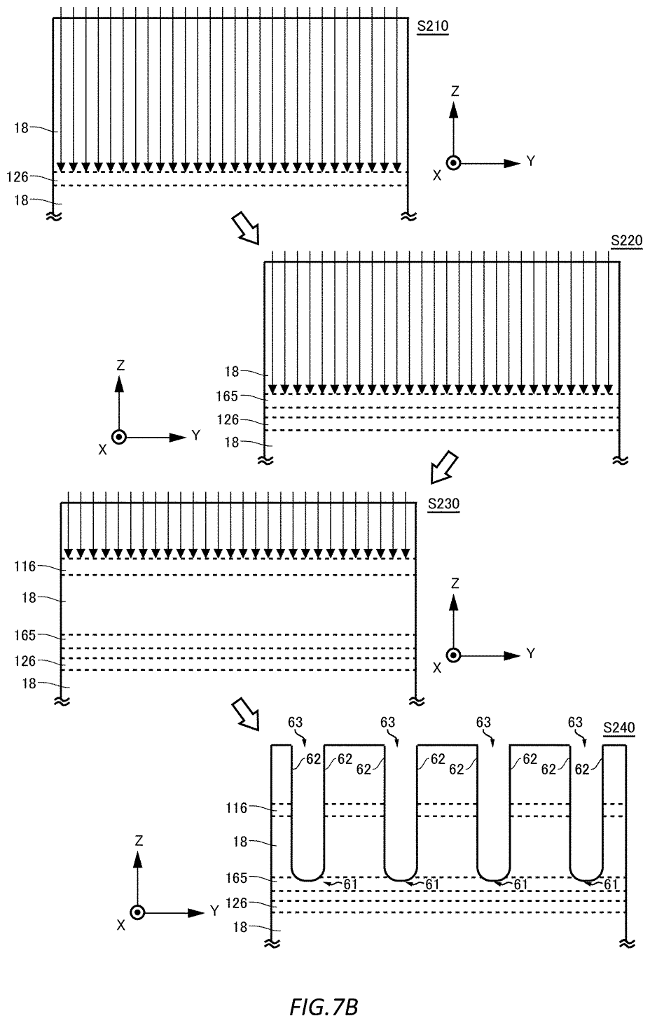

FIG. 7A is a flowchart showing a modified example of a process to manufacture the semiconductor device 100. In the modified example shown in FIG. 7A, regions are formed in order different from that in the example shown in FIG. 6A. Differences from the example shown in FIG. 6A will be described below.

In a step S210, the second accumulation region 26 is formed. Similarly to the example shown in FIG. 6A, the first accumulation region 16 may be formed simultaneously. An acceleration voltage for ion implantation when forming the second accumulation region 26 may be 8.0 MeV or higher, and may be 10.0 MeV or lower.

In a step S220, the trench bottom region 65 is formed. The trench bottom region 65 is formed closer to the front surface 21 of the semiconductor substrate 10 than the second accumulation region 26. An acceleration voltage for ion implantation when forming the trench bottom region 65 may be lower than the acceleration voltage for the ion implantation when forming the second accumulation region 26. The acceleration voltage for the ion implantation when forming the trench bottom region 65 may be 3.0 MeV or higher, and may be 5.0 MeV or lower.

In a step S230, the first accumulation region 16 is formed. The first accumulation region 16 is formed closer to the front surface 21 of the semiconductor substrate 10 than the trench bottom region 65. The first accumulation region 16 may be formed by performing ion implantation once, or may be formed by performing ion implantation multiple times. When the first accumulation region 16 is formed by performing the ion implantation multiple times, a doping concentration in the first accumulation region 16 can have a profile including a flat region.

In the step S230, an acceleration voltage for ion implantation when forming the first accumulation region 16 may be lower than the acceleration voltage for the ion implantation when forming the trench bottom region 65. The acceleration voltage for the ion implantation when forming the first accumulation region 16 may be 2.0 MeV or higher, and may be 4.0 MeV or lower.

In a step S240, a plurality of trench portions are formed on the front surface 21 of the semiconductor substrate 10. That is, in the modified example shown in FIG. 7A, a step of forming the second accumulation region 26, a step of forming the trench bottom region 65, and a step of forming the first accumulation region 16 are performed before a step of forming the plurality of trench portions. This makes it possible to uniformize concentration distributions in the second accumulation region 26, the trench bottom region 65, and the first accumulation region 16 in a trench array direction and to reduce a variation in characteristics of the semiconductor device 100.

FIG. 7B illustrates a modified example of a process to manufacture the semiconductor device 100. FIG. 7B illustrates a YZ cross section of the semiconductor substrate 10 in each step in FIG. 7A.

In the step S210, the second ion implantation region 126 is formed by ion-implanting dopants from the front surface 21 side, on which the drift region 18 is formed, of the semiconductor substrate 10. The second ion implantation region 126 is a region which becomes the second accumulation region 26 through annealing processing.

In the step S220, the trench bottom implantation region 165 is formed by ion-implanting dopants from the front surface 21 side of the semiconductor substrate 10. The trench bottom implantation region 165 is a region which becomes the trench bottom region 65 through annealing processing. In the step S220, making the acceleration voltage during ion implantation lower than in the step S210 can form the trench bottom implantation region 165 closer to the front surface 21 of the semiconductor substrate 10 than the second ion implantation region 126.

In the step S230, the first ion implantation region 116 is formed by ion-implanting dopants from the front surface 21 side of the semiconductor substrate 10. The first ion implantation region 116 is a region which becomes the first accumulation region 16 through annealing processing. The dopants used to form the first ion implantation region 116 may be the same as or different from the dopants used to form the second ion implantation region 126. FIG. 7B shows one example in which the first ion implantation region 116 is formed by performing ion implantation once.

In a step S240, a plurality of trench portions are formed on the front surface 21 of the semiconductor substrate 10. Each of the plurality of trench portions each includes the bottom portion 61, the side wall 62, and the opening 63. Each of the plurality of trench portions is formed such that the bottom portion 61 is located in the trench bottom implantation region 165.

In the above description, in FIG. 7A and FIG. 7B, the regions are formed in order of the second ion implantation region 126, the trench bottom implantation region 165, and the first ion implantation region 116, but the present invention is not limited to this. That is, the step S210, the step S220, and the step S230 may be executed in any order, and the regions may be formed in order of the second ion implantation region 126, the first ion implantation region 116, and the trench bottom implantation region 165. In the modified examples shown in FIG. 7A and FIG. 7B, there is no need to form the mask 64 on the front surface 21 of the semiconductor substrate 10, allowing cost reduction relative to the examples shown in FIG. 6A and FIG. 6B.

While the present invention has been described by way of the embodiments, the technical scope of the present invention is not limited to the above-described embodiments. It is apparent to persons skilled in the art that various alterations or improvements can be made to the above described embodiments. It is also apparent from the description of the claims that embodiments added with such alterations or improvements can be included in the technical scope of the present invention.

Note that the operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the operation flow is described by using phrases such as “first” or “next” in the scope of the claims, specification, or drawings, it does not necessarily mean that the process must be performed in this order.

### EXPLANATION OF REFERENCES

10: semiconductor substrate, 12: emitter region, 14: base region, 15: contact region, 16: first accumulation region, 17: well region, 18: drift region, 19: anode region, 21: front surface, 22: collector region, 23: back surface, 24: collector electrode, 25: connection portion, 26: second accumulation region, 30: dummy trench portion, 31: extending part, 32: dummy dielectric film, 33: connection part, 34: dummy conductive portion, 38: interlayer dielectric film, 40: gate trench portion, 41: extending part, 42: gate dielectric film, 43: connection part, 44: gate conductive portion, 50: gate metal layer, 52: emitter electrode, 54: contact hole, 55: contact hole, 56: contact hole, 61: bottom portion, 62: side wall, 63: opening, 64: mask, 65: trench bottom region, 66: carrier passage region, 67: protruding part, 70: transistor portion, 71: mesa portion, 80: diode portion, 81: mesa portion, 82: cathode region, 90: boundary portion, 91: mesa portion, 100: semiconductor device, 116: first ion implantation region, 126: second ion implantation region, and 165: trench bottom implantation region.

What is claimed is:

1. A semiconductor device comprising a transistor portion, the semiconductor device comprising:
a plurality of trench portions provided on a front surface of a semiconductor substrate and including a gate trench portion;
a drift region of a first conductivity type provided in the semiconductor substrate;
a base region of a second conductivity type provided above the drift region;
an emitter region of the first conductivity type provided above the base region and having a higher doping concentration than the drift region;
a first accumulation region of the first conductivity type provided below the base region and having a higher doping concentration than the drift region;
a trench bottom region of the second conductivity type provided below the first accumulation region and having a higher doping concentration than the base region; and
a second accumulation region of the first conductivity type provided at a position deeper than that of the trench bottom region in a depth direction of the semiconductor substrate and having a higher doping concentration than the drift region, wherein
the transistor portion includes a collector region of the second conductivity type on a back surface of the semiconductor substrate.

2. The semiconductor device according to claim 1, wherein
an upper end of the trench bottom region is in contact with a lower end of the first accumulation region.

3. The semiconductor device according to claim 1, wherein
a lower end of the trench bottom region is in contact with an upper end of the second accumulation region.

4. The semiconductor device according to claim 1, wherein
the trench bottom region is provided extending from a lower end of one trench portion of the plurality of trench portions to a lower end of another trench portion, which faces the one trench portion, of the plurality of trench portions, in a trench array direction of the plurality of trench portions.

5. The semiconductor device according to claim 1, wherein
a thickness of the trench bottom region in the depth direction of the semiconductor substrate is equal to or larger than 20% and equal to or smaller than 100% of a trench depth of the plurality of trench portions.

6. The semiconductor device according to claim 1, wherein
a thickness of the trench bottom region in the depth direction of the semiconductor substrate is 1 μm or larger and 5 μm or smaller.

7. The semiconductor device according to claim 1, wherein
the trench bottom region has:
first regions provided below the plurality of trench portions; and
second regions provided below mesa portions sandwiched between the plurality of trench portions, and
a doping concentration in the first regions is higher than a doping concentration in the second regions.

8. The semiconductor device according to claim 1, wherein
the trench bottom region has:
first regions provided below the plurality of trench portions; and
second regions provided below mesa portions sandwiched between the plurality of trench portions, and
a doping concentration in the first regions is the same as a doping concentration in the second regions.

9. The semiconductor device according to claim 1, comprising
a carrier passage region of the first conductivity type which is not provided with the trench bottom region below the first accumulation region.

10. The semiconductor device according to claim 1, wherein
the second accumulation region has a protruding part protruding from below the trench bottom region beyond an end portion of the trench bottom region toward an outside of the trench bottom region in a trench array direction of the plurality of trench portions.

11. The semiconductor device according to claim 1, wherein
a doping concentration in the first accumulation region has a profile in which a region having a doping concentration equal to or higher than 50% of a maximum doping concentration in the first accumulation region occupies a thickness equal to or larger than 60% and equal to or smaller than 100% of a thickness of the first accumulation region in the depth direction of the semiconductor substrate.

12. The semiconductor device according to claim 1, wherein
a doping concentration in the first accumulation region has one or more doping concentration peaks in the depth direction of the semiconductor substrate.

13. The semiconductor device according to claim 11, wherein
in the depth direction of the semiconductor substrate, the region having the doping concentration equal to or higher than 50% of the maximum doping concentration in the first accumulation region has a thickness of 1 μm or larger and 4 μm or smaller.

14. The semiconductor device according to claim 1, wherein
a doping concentration in the first accumulation region is different from a doping concentration in the second accumulation region.

15. The semiconductor device according to claim 1, comprising
a diode portion having a cathode region of the first conductivity type on the back surface of the semiconductor substrate, wherein
in the diode portion, lower ends of the plurality of trench portions are in contact with a region of the first conductivity type.

16. A method for manufacturing a semiconductor device including a transistor portion, the method comprising:
forming a plurality of trench portions on a front surface of a semiconductor substrate;
forming a base region of a second conductivity type provided above a drift region of a first conductivity type;
forming, above the base region, an emitter region of the first conductivity type having a higher doping concentration than the drift region;
forming a first accumulation region of the first conductivity type having a higher doping concentration than the drift region by ion-implanting dopants from a front surface side of the semiconductor substrate;
forming, below the first accumulation region, a trench bottom region of the second conductivity type having a higher doping concentration than the base region by ion-implanting dopants from the front surface side of the semiconductor substrate; and
forming, at a position deeper than that of the trench bottom region in a depth direction of the semiconductor substrate, a second accumulation region of the first conductivity type having a higher doping concentration than the drift region by ion-implanting dopants from the front surface side of the semiconductor substrate, wherein
the transistor portion includes a collector region of the second conductivity type on a back surface of the semiconductor substrate.

17. The method for manufacturing a semiconductor device according to claim 16, wherein
the forming the first accumulation region has implanting dopants into side walls of the plurality of trench portions via openings of the plurality of trench portions from a direction having a predetermined slope with respect to the depth direction of the semiconductor substrate.

18. The method for manufacturing a semiconductor device according to claim 16, wherein
the forming the trench bottom region has implanting dopants into bottom portions of the plurality of trench portions via openings of the plurality of trench portions in the depth direction of the semiconductor substrate.

19. The method for manufacturing a semiconductor device according to claim 16, wherein
the forming the second accumulation region has implanting dopants into bottom portions of the plurality of trench portions via openings of the plurality of trench portions from a direction having a predetermined slope with respect to the depth direction of the semiconductor substrate.

20. The method for manufacturing a semiconductor device according to claim 16, comprising
the forming the first accumulation region and implanting an ion in order to form the second accumulation region, wherein
the implanting the ion has: forming the first accumulation region by implanting dopants into side walls of the plurality of trench portions via openings of the plurality of trench portions;
and forming the second accumulation region by implanting the dopants into bottom portions of the plurality of trench portions via the openings of the plurality of trench portions.

21. The method for manufacturing a semiconductor device according to claim 16, wherein
the forming the second accumulation region, the forming the trench bottom region, and the forming the first accumulation region are performed before the forming the plurality of trench portions.
